(19) United States
(12) Patent Application Publication
(10) Pub. No.: US 2024/0321505 A1
(43) Pub. Date: Sep. 26, 2024

(54) SYSTEM AND METHOD FOR THREE-PHASE DYNAMIC WIRELESS POWER TRANSFER WITH NEAR CONSTANT OUTPUT POWER

(71) Applicant: Purdue Research Foundation, West Lafayette, IN (US)

(72) Inventors: Aaron Dean Brovont, West Lafayette, IN (US); Dionysios Aliprantis, West Lafayette, IN (US); Steven D. Pekarek, West Lafayette, IN (US)

(73) Assignee: Purdue Research Foundation, West Lafayette, IN (US)

(21) Appl. No.: 18/607,155

(22) Filed: Mar. 15, 2024

Related U.S. Application Data
(60) Provisional application No. 63/452,413, filed on Mar. 15, 2023.

(51) Int. Cl. H01F 27/28; G06F 30/39; H02J 50/10

(52) U.S. Cl. CPC H01F 27/2823; G06F 30/39; H02J 50/10

(57) ABSTRACT

A method of optimizing coil designs in a three-phase dynamic wireless power transfer (DWPT) system is disclosed which includes A) providing a plurality of variables associated with coil designs along with valid ranges for each variable, B) providing a plurality of constant parameters associated with the DWPT system, C) establishing a physical candidate design that has been optimized based on the variables that maximizes a magnetic coupling factor k based on a sequence-coupling factor σ, D) determining an objective function of a multi-objective optimization, E) iteratively generating, evaluating, and selecting a set of candidate designs until a converged non-dominated set of solutions is determined for the magnetic coupling factor k and the sequence coupling factor σ, and F) outputting a finalized design based on the last set of candidate designs resulting from (E).

### CROSS-REFERENCE TO RELATED APPLICATIONS

The present non-provisional patent application is related to and claims the priority benefit of U.S. Provisional Patent Application Ser. No. 63/452,413, filed Mar. 15, 2023, the contents of which are hereby incorporated by reference in its entirety into the present disclosure.

### STATEMENT REGARDING GOVERNMENT FUNDING

This invention was made with government support under grant 1941524, awarded by the National Science Foundation. The government has certain rights in the invention.

### TECHNICAL FIELD

The present disclosure generally relates to wireless power transfer and in particular to a dynamic wireless power transfer (DWPT) system for electric vehicles.

### BACKGROUND

This section introduces aspects that may help facilitate a better understanding of the disclosure. Accordingly, these statements are to be read in this light and are not to be understood as admissions about what is or is not prior art.

Electric vehicles are becoming ubiquitous in the vehicular transportation regime, whether for transporting humans or cargo. However, the charging infrastructure is lagging. In particular, while wired charging stations are continuously added, these wired charging stations are few and far between to accommodate the growing demand for electric vehicles. In concert with adding new wired charging stations, there has been an effort to incorporate dynamic wireless power transfer (DWPT) coils into roadways. Several approaches have been implemented, each with their own challenges.

Generally, it is difficult to accommodate the power needs of electric vehicles, and in particular heavy duty vehicles (HDVs) with single-phase topologies. Therefore, three-phase solutions have been considered for HDV DWPT systems. A three-phase topology includes a three-phase transmitter in the roadway and a three-phase receiver in the vehicle. The magnetic poles can travel along the roadway (in the direction of vehicle motion) or transverse to the roadway (orthogonal to vehicle motion). An advantage of the latter is that the receiver can be readily scaled lengthwise to meet a range of power ratings. However, a noted shortcoming of three-phase transmitter and receiver systems is magnetic imbalance, leading to power fluctuation and poor current/voltage sharing among phases.

In general, power fluctuation arises from four sources: (1) segmentation of the transmitter windings, (2) ac-dc rectification, (3) variation of tx-rx mutual coupling due to vehicle travel, and (4) interphase-mutual-coupling imbalance. Source 1 depends on a wide range of high-level, multidisciplinary system architecture choices, where the frequency of fluctuation depends on coil spacing and vehicle velocity. Since the focus in the present disclosure is the mitigation of higher-frequency oscillations originating from the electrical system, this is not considered further. Considering source 2, polyphase (e.g., three-phase) topologies are inherently capable of delivering lower-ripple power at the output of a passive rectifier compared to single-phase topologies. With regard to source 3, disclosure in prior art demonstrate that polyphase designs can reduce variation in mutual coupling for DWPT systems with magnetic poles oriented along the road; whereas topologies with poles across the road (single-phase and polyphase) naturally achieve good flux continuity during vehicle travel. Unfortunately, polyphase DWPT systems reduce power fluctuation due to sources 2 and 3 at the cost of introducing source 4. However, with all the improvements shown in the prior art, reducing or uniformly balancing mutual couplings in a three-phase DWPT system in order to generate near constant output power still eludes us.

Therefore, there is an unmet need for a novel system and method of mutual coupling between a three-phase transmitter coil setup in the roadway and the three-phase receiver coil setup in a vehicle such that a dynamic wireless power transfer (DWPT) system produces near constant output power without adding external compensation components to balance the phases.

### SUMMARY

A method of optimizing coil designs in a three-phase dynamic wireless power transfer (DWPT) system is disclosed. The method includes A) providing a plurality of variables associated with coil designs of coils in a transmitter and coils in a receiver of the DWPT system along with valid ranges for each variable of said plurality of variables, B) providing a plurality of constant parameters associated with the DWPT system, C) establishing a physical candidate design that has been optimized based on the plurality of variables and their provided ranges that maximizes a magnetic coupling factor k for a minimized positive-to-negative sequence coupling quantified based on a sequence-coupling factor σ, thus evaluating positive-to-negative sequence coupling, D) determining an objective function of a multi-objective optimization. The method also includes E) iteratively generating, evaluating, and selecting a set of candidate designs until a converged non-dominated set of solutions is determined for the magnetic coupling factor k and the sequence coupling factor o, and F) outputting a finalized design based on the last set of candidate designs resulting from (E).

An optimized coil design in a three-phase dynamic wireless power transfer (DWPT) system is also disclosed. The optimized coil design includes a first coil arrangement having three coils (C_{A}, C_{B}, and C_{C}), each coil constituting at least one cable disposed in a form and crossing each of the other two coils including two parallel straight segments and two parallel loop segments. The three coils thus representing self-inductances (L_{A}, L_{B}, and L_{C}) as well mutual inductance (L_{AB}, L_{BC}, and L_{AC}). The self-inductance and mutual inductance of the three coils are governed by inequalities:

$$\begin{matrix}{Low}_{1} < \frac{{L}_{A} + 2 {L}_{B C}}{{L}_{B} + 2 {L}_{C A}} \leq {High}_{1} \\ {Low}_{2} < \frac{{L}_{A} + 2 {L}_{B C}}{{L}_{C} + 2 {L}_{A B}} \leq {High}_{2} \\ {Low}_{3} < \frac{{L}_{B} + 2 {L}_{C A}}{{L}_{C} + 2 {L}_{A B}} \leq {High}_{3}\end{matrix}$$

wherein Low₁ is about 0.5 and High is about 2.
Low₂ is about 0.5 and High₂ is about 2, and
Low₃ is about 0.5 and High₃ is about 2.

### BRIEF DESCRIPTION OF FIGURES

FIG. 1a is a schematic of a power transfer system, according to the present disclosure, in which each circle denotes a conductor wire as part of a corresponding coil, with a dot within a circle representing electrical current defined as positive coming out of the page and a cross within a circle denoting electrical current defined as positive going into the page.

FIG. 1b is a phasor diagram of a balanced system.

FIG. 1c is a phasor diagram of an unbalanced system in which the unbalanced constitutes (IA′, IB′, and IC′) do not have the same magnitude and/or the same angular disposition.

FIG. 1d is a phasor diagram with positive phasors denoted as IA1, IB1, and IC1.

FIG. 1e is a phasor diagram with negative phasors denoted as IA2, IB2, and IC2.

FIG. 1f is a phasor diagram with zero phasors denoted as IA0, IB0, and IC0.

FIG. 1g is a schematic of the transmitter and receiver depicting various parameters as discussed herein.

FIG. 1h is a simplified schematic of how the coils are disposed in a three-dimensional cartesian coordinate system.

FIG. 2a is a schematic of a T-equivalent circuit, according to the present disclosure.

FIG. 2b is a block diagram of the process described in the present disclosure.

FIG. 3 is a graph of magnetic coupling factor vs. sequence coupling factor depicting how optimization produced a set of designs, often referred to as the Pareto-optimal front, with various designs called out therein.

FIG. 4 is a schematic of an elementary system that is used for simulations that were performed for each of the selected designs called out in FIG. 3 to verify that the optimized designs reduce undesirable effects due to sequence interaction.

FIG. 5 is a graph of power in kW/m vs. time in μs representing steady-state simulated output power for the selected designs called out in FIG. 3.

FIG. 6 is an image of a laboratory prototype of the transmitter/receiver topology, according to the present disclosure.

FIGS. 7a 7b, and 7c are graphs of current in A (FIG. 7a), current in A (FIG. 7b) and power in KW (FIG. 7c) vs. time in us showing measured transmitter (FIG. 7a) and receiver (FIG. 7b) phase currents and load power (FIG. 7c).

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 10%, within 5%, or within 1% of a stated value or of a stated limit of a range.

In the present disclosure, the term “substantially” can allow for a degree of variability in a value or range, for example, within 90%, within 95%, or within 99% of a stated value or of a stated limit of a range.

A novel system and method of mutual coupling between a three-phase transmitter coil setup in the roadway and the three-phase receiver coil setup in a vehicle is disclosed herein such that a dynamic wireless power transfer (DWPT) system produces near constant output power without adding external compensation components to balance the phases. Towards this end, the disclosed system substantially eliminates power oscillation and voltage/current sharing issues that have plagued planar three-phase DWPT systems of the prior art. To achieve this goal, a multi-objective optimization scheme is disclosed herein to maximize magnetic coupling and minimize undesired positive-negative sequence coupling. Selected designs are simulated for a 200-kW/m DWPT system, verifying the elimination of power oscillation and phase imbalance with minimal impact on magnetic performance. An actual reduction to practice of a DWPT system is then disclosed, and low-ripple power output is demonstrated at 52-kW operation. Specifically, a symmetrical components (SC)-based transformation of the inductance matrix for a generic pair of three-phase coils yields a T-equivalent circuit with explicit voltage source terms responsible for phase imbalance. It is also shown that these sequence-coupling terms may be eliminated through the design of the tx/rx coil layouts.

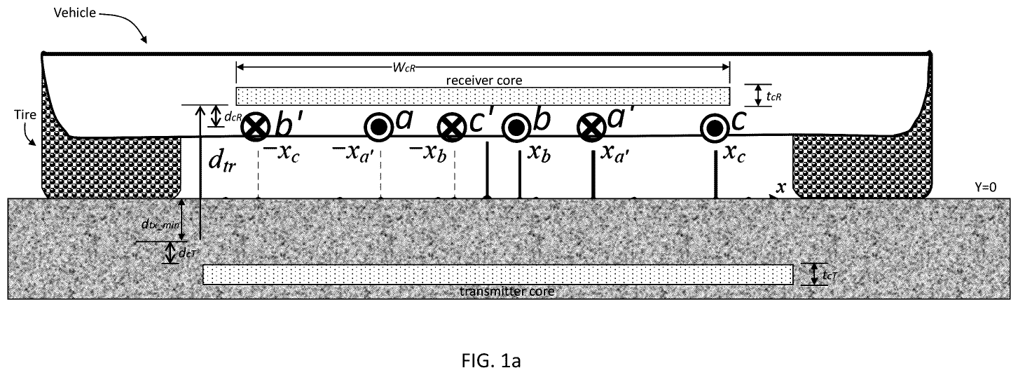

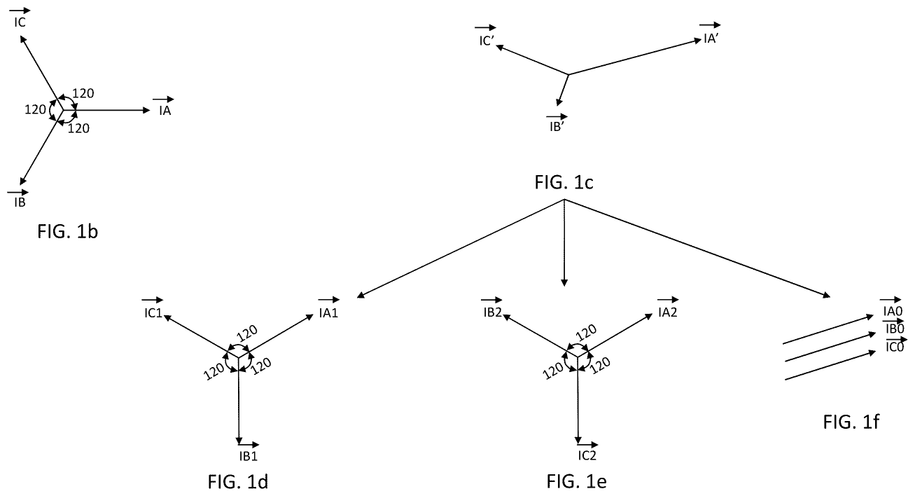

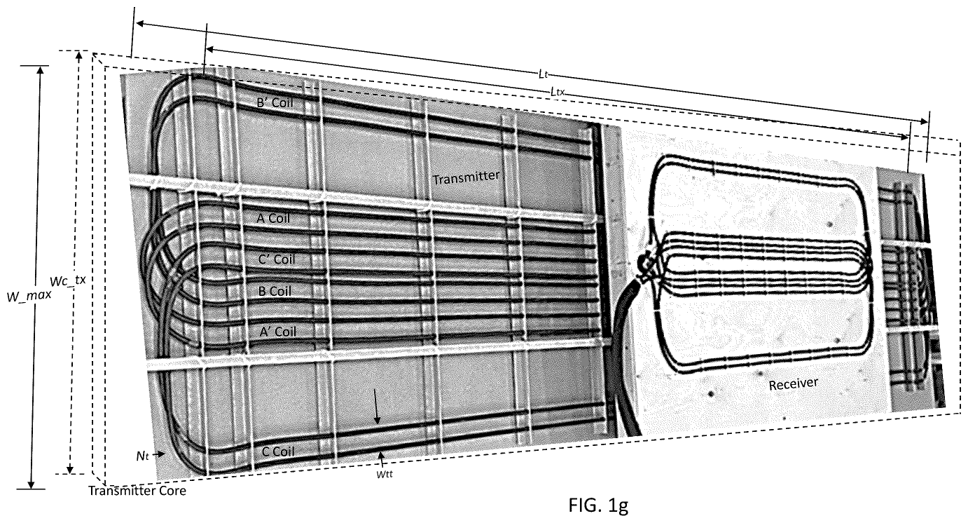

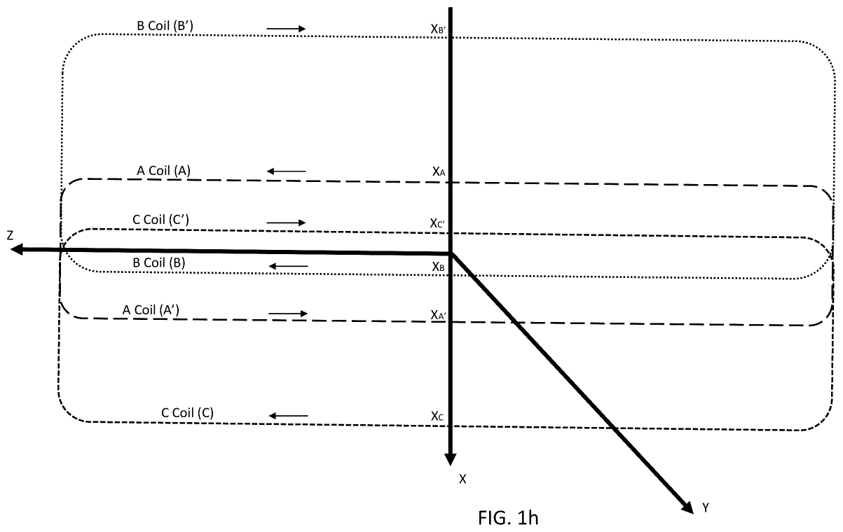

The transverse moving flux topology is shown in FIG. 1a, in which each circle denotes a conductor wire as part of a corresponding coil, with a dot within a circle representing current defined as positive coming out of the page and a cross within a circle denoting current defined as positive going into the page. It should be noted that the aforementioned directionality is only a convention based on the assumption of what positive current signifies. As seen in this topology the coils in the roadway need not be disposed in the same manner as the coils in the vehicle. The dimensions between the coils and the receiver core as well as the dimensions between the conductors of the coil and a centerline and each other are shown in the form of variables, later discussed herein. In FIG. 1a, the transmitter and receiver coils are mirrored with respect to a central vertical line. Therefore, if the dot side of coil C (i.e., the farthest coil (coil C)) is x_{C} away from the centerline, then cross side of coil B (i.e., the nearest coil (coil B)) is also x_{C} away from the centerline on the opposite side of the centerline. Similarly, if the dot side of Coil A is −x_{A}′ away from one side of the centerline, the cross side of coil A is the same x_{A}′ away from the centerline on the opposite side of the centerline. Finally, if the dot side of coil B is x_{B} away from the centerline on one side of the centerline, then the cross side of coil C is also x_{B} away from the centerline on opposite side of the centerline. The same mirror image configuration also holds true for receiver coils.

It should be noted that in FIG. 1a the transmitter coils appear to be disposed in a uniform fashion. That is, the spacing between the coils are about the same. However, the seeming uniformity shown is only to emphasize the lack of uniformity for the receiver side. In practice, the transmitter coils and the receiver coils need not be uniformly disposed with respect to other coils. That is, the transmitter coils can be disposed in a non-uniform manner with respect to other transmitter coils and also with respect to receiver coils. In fact, determination of the positioning of the transmitter and receiver coils is one goal of the method and system of the present disclosure in order to minimize the interphase-mutual-coupling imbalance.

First, a transmitter-receiver equivalent circuit model is discussed. The flux linkage equations for a generic three-phase tx-rx pair (in a magnetically linear system) may be expressed as

$$[ \begin{matrix}{Λ}_{t}^{ABC} \\ {Λ}_{r}^{abc}\end{matrix} ] = [ \begin{matrix}{L}_{t} & {M}_{tr} \\ {( {M}_{tr} )}^{⊤} & {L}_{r}\end{matrix} ] [ \begin{matrix}{I}_{t}^{ABC} \\ {I}_{r}^{abc}\end{matrix} ] \qquad ( 1 a )$$

wherein Λₜ^{ABC} and Λᵣ^{abc} are vectors of phasors, each a 3×1 column vector, representing flux linkage, for the transmitter and receiver coils, respectively;
Lₜ and Lᵣ each represent a 3×3 matrix, representing self- and mutual inductances for the transmitter and receiver coils, respectively;
Mₜᵣ is a 3×3 matrix representing mutual inductance between the transmitter and receiver coils; (Mₜᵣ)^{T} is the transpose of Mₜᵣ;
Iₜ^{ABC} and Iᵣ^{abc} are vectors of phasors, each a 3×1 column vector, representing current through the transmitter and receiver coils, respectively. The inductance matrix is symmetric positive-definite; otherwise, matrix elements are independent.

A classical approach to analyze imbalance in three-phase ac circuits is the SC transformation. A short description of the SC transformation is provided. In a three-phase system, phasors (e.g., current phasors) may be represented as system phasors IA, IB, and IC. Each phasor is defined by a magnitude and an angle with respect to a reference, e.g., the X-axis. In a balanced system, the angle between these phasors is constant (i.e., 120° between each phasor) and the magnitude of each phasor is also the same. Such a balanced system is shown in FIG. 1b. In FIG. 1b, each phasor has the same length and each is 120° positionally away from the other phasors (i.e., that each have the same magnitude, and as shown for example purposes, IA is a phasor having magnitude IA and angle 0°. The system is an ABC phasor system which means for a counterclockwise rotation of the phasors, the sequence of phasors crossing any point is phasor IA, phasor IB, and phasor IC. Now suppose one of the two said conditions (i.e., magnitude or angular disposition) is disturbed, such that the magnitude and/or the angular disposition is not the same for all three phasors. An example imbalance is shown in FIG. 1c, in which the unbalanced constitutes (IA′, IB′, and IC′) do not have the same magnitude and/or the same angular disposition. For example, magnitude of IA′ is different than IB′ and/or IC′ and the angular disposition of IA′, IB′, and IC′ is not defined by 120° between each. For example, this imbalance can be caused by differences in the positioning of one of the receiver coils with respect to the other receiver coils. In order to model this imbalance, the SC transformation is carried out.

The SC transformation transforms the unbalanced constituents (IA′, IB′, and IC′) to balanced phasor constituents denoted by positive, negative, and zero (or as discussed below denoted by: 1, 2, and 0) phasor systems. The positive phasor system in the balanced SC transformation is similar to the balanced phasors shown in FIG. 1a. That is, each phasor has the same magnitude as the other phasors, and each phasor has a 120° phase relationship to the other phasors. The positive phasor system is denoted as IA1, IB1, and IC1 and is shown in FIG. 1d. It should be noted that the sequence of phasors remains the same in the positive phasor system (i.e., ABC). The negative phasor system in the balanced SC transformation is also similar to the balanced phasors, shown in FIG. 1e, except the sequence is changed to ACB. That is, each phasor has the same magnitude as the other phasors, and each phasor has a 120° phase relationship to the other phasors. The negative phasor system is denoted as IA2, IB2, and IC2 as shown in FIG. 1e. For the zero phasor system in the balanced SC transformation each phasor has the same magnitude as the other phasors, and is oriented as the other phasors. The zero phasor system is denoted as IA0, IB0, and IC0 and is shown in FIG. 1f. The critical point to note is that summation of each of the positive, negative, and zero phasors in the balanced SC transformation must equal the corresponding original imbalanced phasor. Thus

$$\vec{IA} = \vec{IA} 1 + \vec{IA} 2 + \vec{IA} 0 ; \vec{IB} = \vec{IB} 1 + \vec{IB} 2 + \vec{IB} 0 ; and \vec{IC} = \vec{IC} 1 + \vec{IC} 2 + \vec{IC} 0.$$

Since the angular disposition of each of IA1, IA2, IC2, and IB1, IB2, IC2 are all the same (i.e.,)120°, the following relationship can be expressed: I_{B1}=I_{A1}·1∠240°, I_{C1}=I_{A1}·1∠120°, I_{B2}=I_{A2}·1∠120°, I_{C2}=I_{A2}·1∠240°, (noting that the negative phasor system has the sequence ACB while the positive phasor system has the sequence ABC). By defining a matrix operation, the above-enumerated relationship can be described as:

$$[ \begin{matrix}IA \\ IB \\ IC\end{matrix} ] = [ \begin{matrix}IA 1 + IA 2 + IA 0 \\ IB 1 + IB 2 + IB 0 \\ IC 1 + IC 2 + IC 0\end{matrix} ] = [ \begin{matrix}IA 1 + IA 2 + IA 0 \\ IA 1 \cdot 1 ∠240 \underline{°} + IA 2 \cdot 1 ∠120 \underline{°} + IA 0 \\ IA 1 \cdot 1 ∠120 \underline{°} + IA 2 \cdot 1 ∠240 \underline{°} + IA 0\end{matrix} ] . \qquad ( 1 b )$$

Notably by making the transformation shown in (1b), the balanced components (9 components: IA1, IA2, IA0, IB1, IB2, IB0, IC1, IC2, IC0) can be reduced to 3 components (IA1, IA2, and IA0), taking advantage of IA0=IBO=IC0. The matrix reduction in (1a) can be further simplified by assigning a complex scalar a as 1∠120° and therefore a²=1∠240°. In this way, (1b) can be rewritten as provided below:

$$[ \begin{matrix}IA \\ IB \\ IC\end{matrix} ] = [ \begin{matrix}IA 1 + IA 2 + IA 0 \\ IA 1 \cdot {a}^{2} + IA 2 \cdot a + IA 0 \\ IA 1 \cdot a + IA 2 \cdot {a}^{2} + IA 0\end{matrix} ] , \qquad ( 1 c )$$

which can be rewritten as:

$$[ \begin{matrix}IA \\ IB \\ IC\end{matrix} ] = [ \begin{matrix}1 & 1 & 1 \\ 1 & {a}^{2} & a \\ 1 & a & {a}^{2}\end{matrix} ] \times [ \begin{matrix}IA 0 \\ IA 1 \\ IA 2\end{matrix} ] \qquad ( 1 d )$$

which can be written simply as:

$$[ \begin{matrix}IA \\ IB \\ IC\end{matrix} ] = A \times [ \begin{matrix}IA 0 \\ IA 1 \\ IA 2\end{matrix} ] , where A = [ \begin{matrix}1 & 1 & 1 \\ 1 & {a}^{2} & a \\ 1 & a & {a}^{2}\end{matrix} ] . \qquad ( 1 e )$$

By determining A⁻¹, the balanced phasors can be determined from the unbalanced phasors as provided by:

$$[ \begin{matrix}IA 0 \\ IA 1 \\ IA 2\end{matrix} ] = {A}^{- 1} \times [ \begin{matrix}IA \\ IB \\ IC\end{matrix} ] , where {A}^{- 1} = 1 / 3 [ \begin{matrix}1 & 1 & 1 \\ 1 & a & {a}^{2} \\ 1 & {a}^{2} & a\end{matrix} ] . \qquad ( 1 f )$$

By introducing the SC transformation matrix A, unbalanced phase quantities in a three-phase system are decomposed as a linear combination of balanced zero-sequence, positive-sequence, and negative-sequence phasor sets (denoted by a 012 superscript):

$${F}_{i}^{abc} {=}^{Δ} {AF}_{i}^{012} \qquad ( 2 )$$

where Fᵢ^{abc} is an unbalanced phasor vector,
and Fᵢ⁰¹² is the balanced phasor vector as derived above.

To apply the SC transformation to the flux linkage equations (1a), we left-multiply the tx/rx equations by A⁻¹, and utilize (2), leading to

$$[ \begin{matrix}{Λ}_{t}^{012} \\ {Λ}_{r}^{012}\end{matrix} ] = [ \begin{matrix}{L}_{t}^{012} & {M}_{tr}^{012} \\ {( {M}_{tr}^{012} )}^{*} & {L}_{r}^{012}\end{matrix} ] [ \begin{matrix}{I}_{t}^{012} \\ {I}_{r}^{012}\end{matrix} ] . \qquad ( 3 )$$

Because the inductance matrix in (1a) is real, the transformed diagonal submatrices are Hermitian, and the off-diagonal sub-matrices are conjugate-transposes of one another. Thus, the inductance matrix transformed into SC is also Hermitian.

We note the following regarding (3). First, for any real matrix P transformed as A⁻¹PA, it can be shown that the positive-and negative-sequence diagonal elements are complex conjugates: e.g., Mₜᵣ²²=Mₜᵣ¹¹*. Furthermore, since the self-inductance submatrices Lₜ⁰¹² and Lᵣ⁰¹² are Hermitian, we can define real-valued tx/rx sequence self-inductances:

$$\begin{matrix}{L}_{T} {=}^{Δ} {L}_{t}^{11} = {L}_{t}^{22} ϵℝ , & {L}_{R} {=}^{Δ} {L}_{r}^{11} = {L}_{r}^{22} ϵℝ .\end{matrix} \qquad ( 4 )$$

Second, it can be shown that the imaginary part of Mₜᵣ¹¹ (and Mₜᵣ²²) is negligible for the topology considered herein. Hence, for simplicity, we define a sequence mutual inductance

$$M {=}^{Δ} Re \{ {M}_{tr}^{11} \} = Re \{ {M}_{tr}^{22} \} . \qquad ( 5 )$$

Third, it can be shown that the positive-negative-sequence off-diagonal elements are complex conjugates: i.e., Lₜ²¹=Lₜ¹²*, Lᵣ²¹=Lᵣ¹²*, and Mₜᵣ²¹=Mₜᵣ¹²*. Fourth, it is convenient to refer the rx-side quantities to the tx side as is typical for transformers, using the “turns ratio” factor: n≙\sqrt{L_{R}/L_{T}}. Finally, it is assumed that the zero sequence can be neglected for the purpose of analyzing power transfer. Under these conditions and simplifications, the positive-sequence equations of (3) can be expressed as

$$[ \begin{matrix}\text{?} \\ \text{?}\end{matrix} ] = [ \begin{matrix}{L}_{T} & {M}^{′} \\ {M}^{′} & {L}_{T}\end{matrix} ] [ \begin{matrix}\text{?} \\ \text{?}\end{matrix} ] + [ \begin{matrix}{L}_{t}^{12} & {M}_{tr}^{12 ′} \\ {M}_{tr}^{12 ′} & {L}_{r}^{12 ′}\end{matrix} ] [ \begin{matrix}{I}_{t}^{2} \\ {I}_{r}^{2 ′}\end{matrix} ] . \qquad ( 6 )$$

$$\text{?} \text{indicates text missing or illegible when filed}$$

The negative-sequence equations are identical in form, except that positive-and negative-sequence variables exchange places, and all elements in the second matrix are conjugated. To avoid interaction between positive-and negative-sequences, it is necessary to eliminate the inductances in the second matrix of (6). To this end, we derive the sequence T-equivalent circuits and express the undesired couplings in a normalized form. Let leakage inductance be defined as

$${L}_{t} {=}^{Δ} {L}_{T} - {M}^{′} . \qquad ( 7 )$$

Splitting the tx/rx self-flux linkages in (6) into leakage and magnetizing components using the definitions in (5) and (7) yields the equations corresponding to a typical T-equivalent circuit with additional undesired terms representing sequence interaction. These sequence-coupling terms may be expressed in terms of voltages with normalized coefficients by defining leakage and magnetizing flux linkages as

$${Λ}_{Ll , t}^{x} {=}^{Δ} {L}_{l} {I}_{t}^{x} , {Λ}_{M}^{x} {=}^{Δ} {M}^{′} ( {I}_{t}^{x} + {I}_{r}^{x ′} ) , {Λ}_{Ll , r}^{x ′} {=}^{Δ} {L}_{l} {I}_{r}^{x ′} , \qquad ( 8 )$$

where x∈{1, 2}. Finally, replacing the negative-sequence currents of (6) with corresponding expressions from (8) yields:

$$\text{?} = \text{?} + {M}^{′} ( \text{?} + \text{?} ) + \frac{{L}_{t}^{12} - {M}_{tr}^{12 ′}}{\text{?}} \text{?} + \frac{{M}_{tr}^{12 ′}}{{M}^{′}} {Λ}_{M}^{2} \qquad ( 9 )$$

$$\text{?} \text{indicates text missing or illegible when filed}$$

and

$$\text{?} = \text{?} + {M}^{′} ( \text{?} + \text{?} ) + \frac{{L}_{r}^{12 ′} - {M}_{tr}^{12 ′}}{\text{?}} \text{?} + \frac{{M}_{tr}^{12 ′}}{{M}^{′}} {Λ}_{M}^{2} . \qquad ( 10 )$$

$$\text{?} \text{indicates text missing or illegible when filed}$$

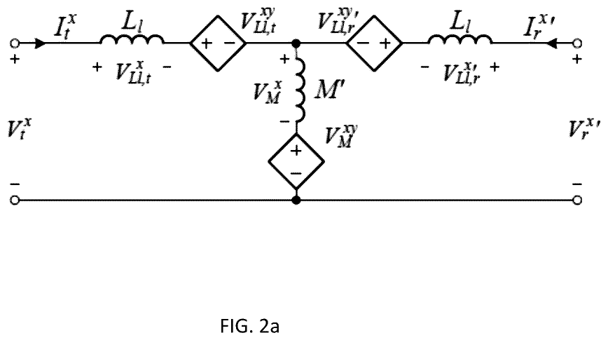

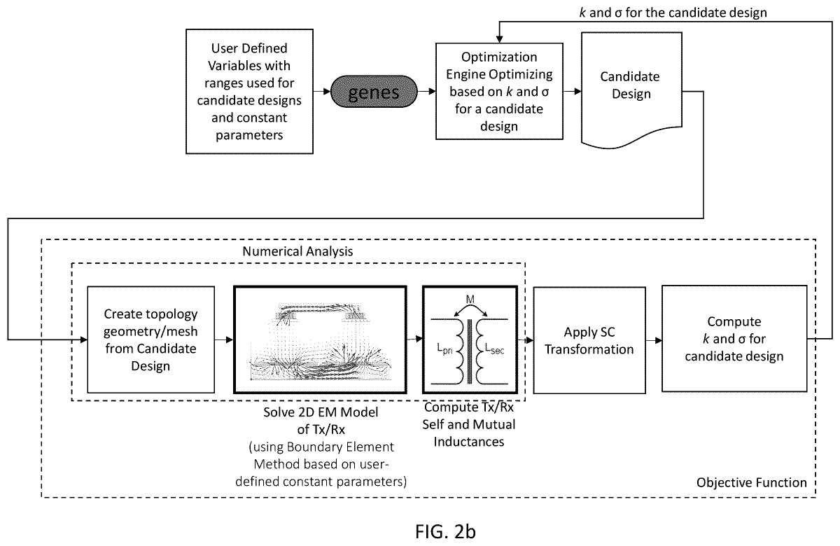

Equations (9) and (10) imply a T-equivalent circuit of the form shown in FIG. 2a, where the dependent voltage sources (i.e., V_{L1,t}^{xy}, V_{L1,r}^{xy}, and V_{M}^{xy}) correspond to the last two terms of equations (9) and (10), with V=jω∧ (resistances are not included for clarity).

Coil design optimization is now disclosed. According to the present disclosure, a sequence interaction for planar windings is reduced without significant magnetic performance degradation. Specifically, to eliminate the sequence coupling in the magnetizing branch of FIG. 2a, the coefficient Mₜ¹²′/M′ of equation (10) must vanish. Accordingly, (9) and (10) indicate that the remaining factors to minimize are Lₜ¹²/L₁ and Lₜ¹²′/L₁. To aid optimization convergence, it is helpful to define a unitless “sequence-coupling factor” to be minimized, which represents the aggregate effect of these undesirable terms:

$$σ {=}^{Δ} \vert {M}_{tr}^{12 ′} \vert / {M}^{′} + \vert {L}_{t}^{12} \vert / {L}_{1} + \vert {L}_{r}^{12 ′} \vert / {L}_{1} . \qquad ( 11 )$$

A common metric for DWPT magnetic performance, which we wish to maximize, is the coupling factor:

$$k {=}^{Δ} M / \sqrt{{L}_{T} {L}_{R}} , \qquad ( 12 )$$

which is based on the definitions of (4) and (5).

Let x be a vector of geometric parameters defining a candidate design, as indicated in FIG. 1a. Then, the two-objective design problem is given by arg maxₓ {σ⁻¹, k}. As an illustrative case study, an optimization was performed to design transmitter-receiver (tx-rx) pairs on a per-turn, per-length basis. The coil distance dtr was set to 21 cm, and the rx/tx widths were constrained so as not to exceed 0.9 m and 1.2 m, respectively. The receiver core was specified to be MN60 ferrite with thickness t_{rc}=1 cm. This optimization problem was solved using an evolutionary computing toolbox. The tx-rx inductance matrix in (1a) was computed for each candidate design (assuming perfect alignment) using the Boundary Element Method.

It should be noted that the objective function can be based on a plurality of parameters. A list of such parameters is provided in Table 1, provided below.

TABLE 1
Objective function parameters for transmitter and receiver (see FIG. 1a)

| | | | |
|---|---|---|---|
| Parameter | Description | Value | Units |

Transmitter

| | | | |
|---|---|---|---|
| Nₜ | Number of transmitter cable per each phase | 2 | turns/phase |
| lₜ | length of tx | 3.32 | m |
| x_{B} | position of B coil-side | 3.9 | cm |
| x_{A}′ | position of A′ coil-side | 10.7 | cm |
| x_{C} | position of C coil-side | 39.9 | cm |
| wₜₜ | width between tx turns | 4.5 | cm |
| wc_tx | width of tx core | 0.0100 | m |
| d_{cT} | distance between tx coils and tx core | 0.2000 | m |
| | (surface-to-surface) | | |
| t_{cT} | height of tx core | −0.0038 | m |
| ltx_max | max length of tx | 3.6576 | m |
| dtx_min | min depth below surface for tx | 0.0500 | m |
| w_max | max width of tx | 2 | m |
| Npt_tx | number of parallel turns | 1 | turns |
| rctx | tx litz wire gauge | 4 | AWG |
| ltx | active length of tx | 3.3200 | m |
| mu_r | relative permeability | 1 | unitless |
| coreT | Core material | N/A | |

Receiver

| | | | |
|---|---|---|---|
| Nᵣ | number of rx series turns | 2 | turns/phase |
| lᵣ | length of rx | 1.25 | m |
| x_{b} | position of b coil-side | 4.0 | cm |
| xₐ′ | position of a′ coil-side | 8.6 | cm |
| x_{c} | position of c coil-side | 33.7 | cm |
| wᵣₜ | width between rx turns | 3.0 | cm |
| d_{rc} | distance between rx coils and core | 1.3 | cm |
| t_{rc} | thickness of rx core | 1.0 | cm |
| w_{rc} | width of rx core | 71 | cm |
| dyrx | distance between rx coils and rx core | 0.0063 | m |
| | (surface-to-surface) | | |
| dxrx | distance between rx turns | 0.0164 | m |
| | (surface-to-surface) | | |
| yy_rx | y-position of bottom of rx core | 0.1702 | m |
| wcs_rx | width of rx coil-side | 0.0440 | m |
| lrx_max | maximum allowable length of rx | 2 | m |
| drx_min | min height above surface for rx | 0.1500 | m |
| hyrx | thickness of rx core | 0.0100 | m |
| w_max_rx | max width of rx | 2 | m |
| Npt_rx | number of parallel turns | 1 | turns |
| lrx_target | target rx length | 1 | m |
| mu_r | relative permeability | 1.5762e+04 | pu |
| density | material density | 4.8185e+03 | kg/L |
| rrx_conduit | radius of rx conduit | 0.0069 | m |
| trx_conduit | thickness of rx conduit | 0 | m |
| mpl_rx | rx litz wire mass per length | 0.3676 | kg/m |
| Rpl_rx | rx litz wire dc resistance per length | 5.9055e−04 | Ohms/m |
| ODrx_conduit | outer diameter of rx conduit | 0.0138 | m |
| ODwire_rx | outer diameter of rx litz wire | 0.0138 | m |
| yc_rx | y-position of rx conductor centers | 0.1569 | m |
| yymin_rx | min y-position of rx core | 0.1638 | m |

System-Level

| | | | |
|---|---|---|---|
| dₜᵣ | air gap between tx and rx | 21.4 | cm |
| t_sleeve | thickness of conductor jacket/sleeve | 6.3500e−04 | m |
| p_obs | stray field observation points | (x, y) | m |
| Pout | desired output power (transferred by the | 52000 | W |
| | receiver) | | |
| Vin_V | dcinput voltage (input to inverter coupled to | 750 | V |
| | transmitter) | | |
| Tamb | ambient temperature | 70 | deg C. |
| TMax | max winding temperature | 150 | deg C. |
| freq | resonant frequency | 85000 | Hz |
| Vout_V | desired output voltage out of rectifier of | 750 | V |
| | receiver | | |
| rated_volt | maximum rated voltage for coil-to-coil in | 4500 | V |
| | system | | |
| Jmax | max conductor current density for all coils | 15000000 | A/m\hat{ }2 |
| BstrayMax | max stray field | 2.7000e−05 | T |
| current_ratio | ratio of tx to rx operating currents | 1 | unitless |

Each of these parameters is discussed below with reference to FIGS. 1a and 1g. Nₜ represent number of cables in each loop (phase). In FIG. 1g, two cables are shown in each loop. Lₜ represents the length of the transmitter, as shown in FIG. 1g. X_{B}, X_{A}′, and x_{C}, are positions of the corresponding phases, as shown in FIG. 1a. wₜₜ represents the width between two cables in each phase, as shown in FIG. 1g. Wc_tx represents the width of the transmitter core, as shown in FIG. 1g. It should be noted that having a core for either or both the transmitter and the receiver may be optional. d_{cT} is the distance between the transmitter coils and the transmitter core as shown in FIG. 1a. t_{cT} is the height of the transmitter core, as shown in FIG. 1a. ltx_max is the maximum length of the transmitter (Lₜ is shown in FIG. 1g). dtx_min is the minimum depth below the surface for the transmitter coils, as shown in FIG. 1a. W_max is the maximum width of the transmitter as shown in FIG. 1g. Npt_tx represents the number of parallel turns in each coil. It should be noted that each coil, as discussed above, can have more than on cable. For example, in FIG. 1g, each coil (i.e., phase) has two cables. These two cables can be coupled to each other in a parallel fashion (i.e., the voltage at the junction of the two cables is applied to both cables) or in a series fashion (i.e., the current through the two cables is the same). This parameter represents how many parallel connections there are with the number of cables in each coil. Whether the connection is parallel or series is based on how the cables are connected to each other where the cables wrap around at the ends (the connection not shown for the transmitter in FIG. 1g). rctx represents the gauge of the Litz wire used for each cable of each phase. mu_r is the relative permeability of a core material. coreT is the core material for the transmitter. These same parameters apply for the receiver, however, the parameters are not shown in FIG. 1g to avoid overcrowding the figure. The remainder of parameters are described in Table 1.

Referring to FIG. 1h, a simplified schematic of how the coils are distributed in a three-dimensional Cartesian coordinate system. While in FIG. 1g, each coil is shown as having 2 cables (i.e., 2 turns), each coil in FIG. 1h is shown as having one cable. Each coil has a positive side (i.e., electrical current flows parallel to the positive Z-axis and a negative side (i.e., electrical current flows antiparallel to the positive Z-axis) as indicated by arrows shown in FIG. 1h. As shown in FIG. 1h, each coil is disposed in a planar fashion having two elongated segments that are essentially parallel to one another and two looped segments that are also essentially parallel to one another. If, as shown in FIG. 1g and as discussed above, a coil is constructed from two cables, in the looped section, the two cables are tied to one another in a parallel fashion or in a series fashion. The number of cables per coil is at least 1 but can be 2, 3, 4, or more depending on the needs of the system. As shown in FIG. 1h, each coil intercepts the X-axis at a point (i.e., X_{A}, and X_{A′}; X_{B}, and X_{B′}; and X_{C}, and X_{C′}). If more than one cable is used in a coil, then the X-intercept can be taken as a central point between the cables on the X-axis. The positioning of each cable affects these intercept points. Additionally, the coils are extended along the Z-axis, whereby the coils have equal lengths along the Z-axis or different lengths. As discussed below, the position and dimensions of the three coils, should be such that the ratios established by Eq. (13a) and when two such coils are disposed along the Y-axis (i.e., a transmitter and a receiver) by Eq. (13c) in the form of inequalities described by inequalities of (13d) and (13e).

The process described above is shown in the flow diagram in FIG. 2b. To recap, the following steps are carried out to optimize k and σ for a candidate design by an optimization engine:
1) Before any design or optimization occurs, a genetic algorithm (GA) or more generally an Optimization Engine receives from the user three items:
   a. A specification of the genes that define a candidate design (See FIG. 1a);
   b. Valid range of values a gene can assume; and
   c. Values for constant parameters involved in the design (e.g., permeability, etc.).
2) The optimization engine generates a physical candidate design and provides that candidate design to an objective function. The first output of the optimization engine is randomly chosen based on the values provided by the user in (1). The optimization engine selects new candidate designs based on k and o performance of the previous iteration.
3) The objective function carries out the following:
   a. Design geometry is generated and meshed from the candidate's genes as provided by the optimization engine;
   b. A Boundary Element Method is used to numerically solve 2-D Maxwell's equations for the electromagnetic (EM) fields based on the genes supplied by the optimization engine and the constant parameters provided by the user.
   c. Compute self and mutual inductances in a matrix form of and between the transmitter and the receiver coils;
   d. Apply a Symmetric Components (SC) transformation to the computed self and mutual inductances matrix to thereby generate SC inductance matrix;
   e. From the generated SC inductance matrix, compute the magnetic coupling factor k and the sequence coupling factor σ; and
   f. Output the computed magnetic coupling factor k and the sequence coupling factor σ to the optimization engine for the next iteration of the optimization engine.
4) Repeat steps (2) and (3) until a converged non-dominated set of solutions is determined for the magnetic coupling factor k and the sequence coupling factor σ.
5) Output the finalized designs selected from the last candidate designs resulting from (4).

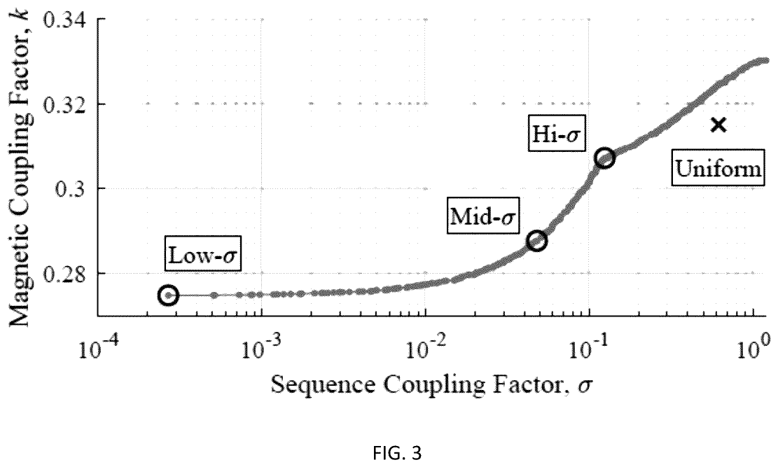

The optimization produced a set of designs, often referred to as the Pareto-optimal front, shown in FIG. 3. The performance metrics of a “uniform” conductor arrangement (spaced equally across the full widths of the tx/rx) are also plotted therein. It can be shown that in an ideal case σ vanishes if

$${L}_{A} + 2 {L}_{BC} = {L}_{B} + 2 {L}_{CA} = {L}_{C} + 2 {L}_{AB} , \qquad ( 13 a )$$

$${L}_{a} + 2 {L}_{bc} = {L}_{b} + 2 {L}_{ca} = {L}_{c} + 2 {L}_{ab} , \qquad ( 13 b )$$

$$\begin{matrix}{M}_{Aa} + {M}_{Bc} + {M}_{Cb} = {M}_{Bb} + {M}_{Ca} + {M}_{Ac} \\ = {M}_{Cc} + {M}_{Ab} + {M}_{Ba}\end{matrix} . \qquad ( 13 c )$$

By establishing ratios as provided below, Eqs. (13a) and 13(C) can be rewritten for real-world non-ideal situations in the form of the following inequalities:

For transmitter:

$${Low}_{1} < \frac{{L}_{A} + 2 {L}_{BC}}{{L}_{B} + 2 {L}_{CA}} \leq {High}_{1} \qquad ( 13 d )$$

$${Low}_{2} < \frac{{L}_{A} + 2 {L}_{BC}}{{L}_{C} + 2 {L}_{AB}} \leq {High}_{2}$$

$${Low}_{3} < \frac{{L}_{B} + 2 {L}_{CA}}{{L}_{C} + 2 {L}_{AB}} \leq {High}_{3}$$

$$For the system :$$

$${Low}_{4} < \frac{{M}_{Aa} + {M}_{Bc} + {M}_{Cb}}{{M}_{Bb} + {M}_{Ca} + {M}_{Ac}} \leq {High}_{4} \qquad ( 13 e )$$

$${Low}_{5} < \frac{{M}_{Aa} + {M}_{Bc} + {M}_{Cb}}{{M}_{Cc} + {M}_{Ab} + {M}_{Ba}} \leq {High}_{5}$$

$${Low}_{6} < \frac{{M}_{Bb} + {M}_{Ca} + {M}_{Ac}}{{M}_{Cc} + {M}_{Ab} + {M}_{Ba}} \leq {High}_{6}$$

$$For the receiver :$$

$${Low}_{1} < \frac{{L}_{a} + 2 {L}_{bc}}{{L}_{b} + 2 {L}_{ca}} \leq {High}_{1} \qquad ( 13 f )$$

$${Low}_{2} < \frac{{L}_{a} + 2 {L}_{bc}}{{L}_{c} + 2 {L}_{ab}} \leq {High}_{2}$$

$${Low}_{3} < \frac{{L}_{b} + 2 {L}_{ca}}{{L}_{c} + 2 {L}_{ab}} \leq {High}_{3}$$

It should be noted that single-subscript “L” terms refer to inductances associated with individual coils and double-subscript “L” terms refer to mutual inductance between coils in either the transmitter or the receiver, while double-subscript “M” terms refer to mutual inductances between the associated coils in the transmitter and receiver. In all these cases the ratios (Low; and Highⱼ) is between 0.5 to 2 and according to one embodiment between 0.95-1.05. It should also be noted that the inductances used to compute these ratios is characterized, according to one embodiment, in the intended operational frequency band of 79-90 kHz with the coil sets aligned as well as possible.

The inductance matrix for the “low-σ” design, reported below for reference, meets these constraints within the tolerance corresponding to the sequence-coupling factor:

$${L}_{tr} = [ \begin{matrix}\begin{matrix}2.143 & - 0.311 & - 0.311 \\ - 0.311 & 2.224 & - 0.27 \\ - 0.311 & - 0.27 & 2.224\end{matrix} & \begin{matrix}0.438 & - 0.33 & - 0.33 \\ - 0.195 & 0.613 & - 0.175 \\ - 0.195 & - 0.175 & 0.613\end{matrix} \\ {( {M}_{tr} )}^{T} & \begin{matrix}2.812 & - 0.465 & - 0.465 \\ - 0.465 & 2.856 & - 0.443 \\ - 0.465 & - 0.443 & 2.856\end{matrix}\end{matrix} ] μH / m . \qquad ( 14 )$$

This result is achieved for (xB, x′_{A}, xC)=(50, 279, 594), (xb, x′ₐ, xc)=(52, 147, 445), w_{rc}=900, and d_{rc}=11 (all in mm) as defined in FIG. 1a.

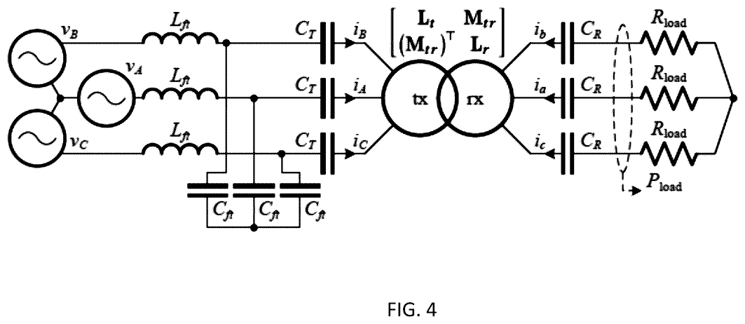

Simulations were performed for each of the selected designs called out in FIG. 3 using the elementary system detailed in FIG. 4 to verify that the optimized designs reduce undesirable effects due to sequence interaction. LCC and series compensation schemes were used to condition the tx and rx, respectively, although the sequence-interaction property of each tx/rx design is independent of the compensation circuit. The compensation circuit elements and load were sized to achieve equal source/load voltages and equal tx/rx currents at ƒo=85 kHz:

$${L}_{ft} = M , {C}_{ft} = {[ {ω}_{0}^{2} {L}_{ft} ]}^{- 1} , {C}_{T} = {[ {ω}_{0}^{2} ( {L}_{T} - {L}_{ft} ) ]}^{- 1} , \qquad ( 15 )$$

$${C}_{R} = {[ {ω}_{0}^{2} {L}_{R} ]}^{- 1} , {R}_{load} = {ω}_{0} M ,$$

where ω₀=2πƒo. The input voltages were an ideal, three-phase set with amplitudes specified to achieve 200 kW/m (kW per m of rx length): {189, 179, 172, 167} Vᵣₘₛ for the Uniform, Hi-σ, Mid-σ, and Low-σ design simulations, respectively.

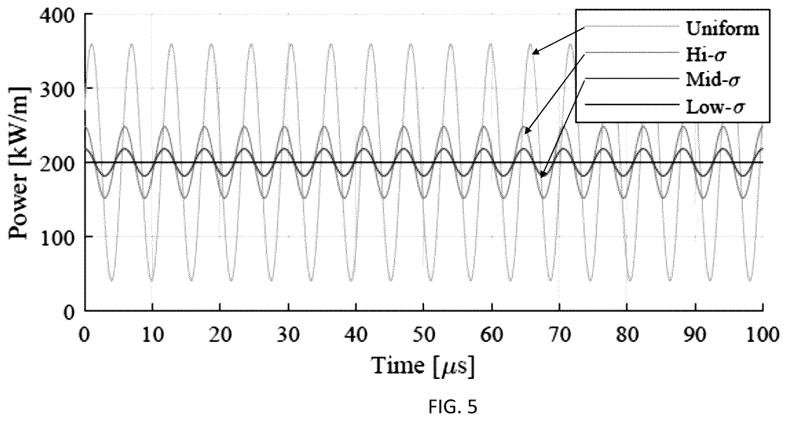

The steady-state simulated output power for the selected designs is plotted in FIG. 5, and key performance data are listed in Table 2. The results indicate that the low-σ tx/rx design does indeed transfer power with minimal output ripple by virtue of balancing the rx currents (and source currents, by extension), which is a vast improvement over the higher-σ and uniform designs. Also, it can be seen in Table 2 that σ correlates well with the output power ripple ΔP_{load}.

TABLE 2
Design Verification Performance Parameters and Metrics

| | k | σ | {I_{A}, I_{B}, I_{C}} | {Iₐ, I_{b}, I_{c}} | ΔP_{load} |
|---|---|---|---|---|---|
| Design | (pu) | (%) | (Arms · turns) | (Arms · turns) | (%) |
| Uniform | 0.315 | 61.6 | {385, 385, 385} | {455, 171, 416} | 80.0 |
| Hi-σ | 0.307 | 12.4 | {368, 368, 368} | {412, 347, 348} | 24.2 |
| Mid-σ | 0.288 | 4.79 | {387, 387, 387} | {405, 379, 379} | 9.16 |
| Low-σ | 0.275 | 0.03 | {398, 398, 398} | {398, 398, 398] | 0.05 |

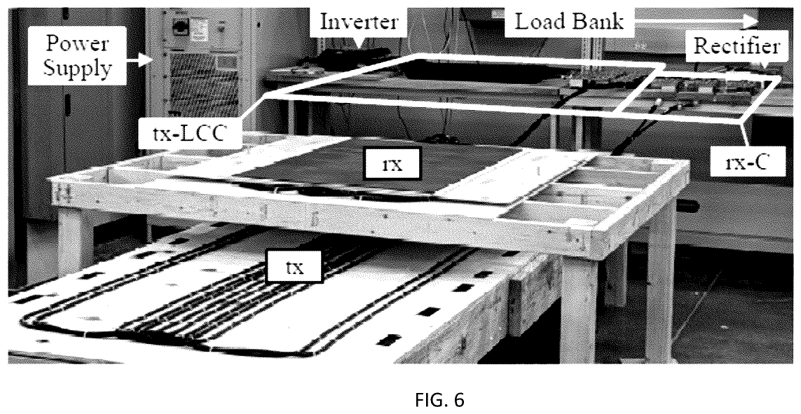

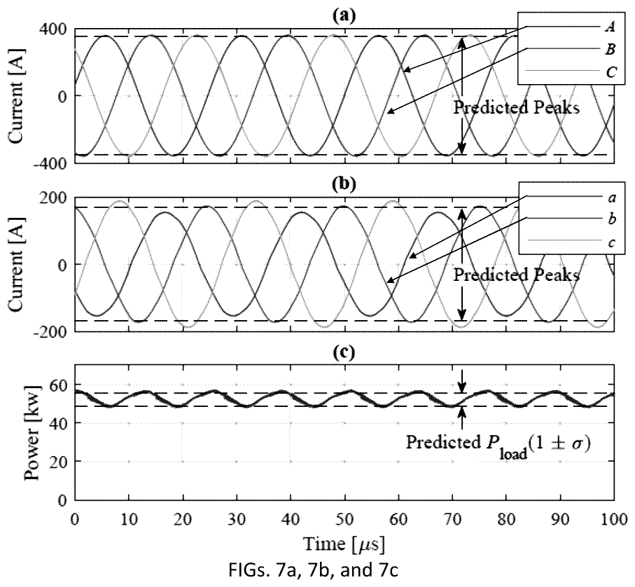

A laboratory prototype of the proposed tx/rx topology was constructed as shown in FIG. 6. The tx/rx were instantiated with two turns each and sized lengthwise to achieve a sequence mutual inductance M=2.37 μH; the characterized value was 2.41 μH. The measured tx and rx sequence self-inductances were 23.4 and 14.6 μH, respectively. The characterized sequence-coupling factor was σ=6.7%, primarily due to imperfect alignment and imbalance in end turns and leads. LCC and series compensation circuits were designed for the tx and rx, respectively, tuned for 40-kHz operation. A silicon carbide (SiC)-based three-phase inverter employing 180°-switching converted a regulated dc supply to a positive-sequence excitation; a SiC-based three-phase passive rectifier at the rx output supplied a resistive load bank. The DWPT system was operated with a dc input of 750 V, achieving output power P_{load}=52 kW. The measured tx and rx phase currents and load power are plotted in FIGS. 7a, 7b, and 7c, respectively. It is observed therein that good balance is achieved between phase currents, and the measured 7.2% power ripple agrees well with the characterized value of σ.

It should be noted that the field of wireless power transfer represents a practical application. For example, nowadays many smartphones are powered via wireless power transfer. Currently or near future electric vehicles will be able to be charged via wireless power transfer as the vehicles are travelling on highways or standing behind stop lights. The present disclosure represents an improvement to this existing and up and coming practical application.

It should be appreciated that while the wireless charging system disclosed herein is discussed in relationship with vehicular charging, no such limitation is intended or should be applied to the topology discussed herein. That is, the same topology can be applied to stationary charging using the same 3-phase approach discussed herein. In both DWPT and stationary approaches, a shielding can be applied to the receiver alone, to the transmitter alone, or to both the receiver and the transmitter, as known to a person having ordinary skill in the art, such that electromagnetic radiation is managed outside of the shielding.

Those having ordinary skill in the art will recognize that numerous modifications can be made to the specific implementations described above. The implementations should not be limited to the particular limitations described. Other implementations may be possible.

1. A method of optimizing coil designs in a three-phase dynamic wireless power transfer (DWPT) system, comprising:
A) providing a plurality of variables associated with coil designs of coils in a transmitter and coils in a receiver of the DWPT system along with valid ranges for each variable of said plurality of variables;
B) providing a plurality of constant parameters associated with the DWPT system;
C) establishing a physical candidate design that has been optimized based on the plurality of variables and their provided ranges that maximizes a magnetic coupling factor k for a minimized positive-to-negative sequence coupling quantified based on a sequence-coupling factor σ, thus evaluating positive-to-negative sequence coupling;
D) determining an objective function of a multi-objective optimization;
E) iteratively generating, evaluating, and selecting a set of candidate designs until a converged non-dominated set of solutions is determined for the magnetic coupling factor k and the sequence coupling factor σ; and
F) outputting a finalized design based on the last set of candidate designs resulting from (E).

2. The method of claim 1, wherein the objection function includes:
i. specifying a design geometry based on a plurality of variables conforming to (A) and a plurality of constant parameters conforming to (B);
ii. numerically solving a set of partial differential equations for the electromagnetic (EM) fields based on a Boundary Element Method and the optimization engine iteratively generated candidate design and the provided plurality of constant parameters;
iii. computing self- and mutual-inductances in a matrix form of and between the transmitter and the receiver coils;
iv. apply a Symmetric Components (SC) transformation to the computed self- and mutual inductances matrix to thereby generate SC inductance matrix;
v. computing the magnetic coupling factor k and the sequence coupling factor σ based on the generated SC inductance matrix; and
vi. outputting the computed magnetic coupling factor k and the sequence coupling factor σ to the optimization engine for a next iteration of the optimization engine

3. The method of claim 1, wherein the optimization engine is based on a genetic algorithm.

4. The method claim 2, wherein the criteria for the optimized computed magnetic coupling factor k and the sequence coupling factor σ is associated with when the performance of the non-dominated set of designs has converged.

5. The method of claim 2, wherein the design geometry is based on the plurality of variables for the transmitter.

6. The method of claim 5, wherein the plurality of variables for the transmitter includes:

| Parameter | Description | Units |
|---|---|---|
| Nₜ | Number of transmitter cable per each phase | turns/phase |
| lₜ | length of tx | m |
| x_{B} | position of B coil-side | cm |
| x_{A}′ | position of A′ coil-side | cm |
| x_{C} | position of C coil-side | cm |
| wₜₜ | width between tx turns | cm |
| wc_tx | width of tx core | m |
| d_{cT} | distance between tx coils and tx core | m |
| | (surface-to-surface) | |
| t_{cT} | height of tx core | m |
| ltx_max | max length of tx | m |
| dtx_min | min depth below surface for tx | m |
| w_max | max width of tx | m |
| Npt_tx | number of parallel turns | turns |
| rctx | tx litz wire gauge | AWG |
| ltx | active length of tx | m |
| mu_r | relative permeability | unitless |
| coreT | Core material | |

7. The method of claim 2, wherein the design geometry is based on a plurality of variables for the receiver.

8. The method of claim 7, wherein the plurality of variables for the received includes:

| Parameter | Description | Units |
|---|---|---|
| Nᵣ | number of rx series turns | turns/phase |
| lᵣ | length of rx | m |
| x_{b} | position of b coil-side | cm |
| xₐ′ | position of a′ coil-side | cm |
| x_{c} | position of c coil-side | cm |
| wᵣₜ | width between rx turns | cm |
| d_{rc} | distance between rx coils and core | cm |
| t_{rc} | thickness of rx core | cm |
| w_{rc} | width of rx core | cm |
| dyrx | distance between rx coils and rx core | m |
| | (surface-to-surface) | |
| dxrx | distance between rx turns | m |
| | (surface-to-surface) | |
| yy_rx | y-position of bottom of rx core | m |
| wcs_rx | width of rx coil-side | m |
| lrx_max | maximum allowable length of rx | m |
| drx_min | min height above surface for rx | m |
| hyrx | thickness of rx core | m |
| w_max_rx | max width of rx | m |
| Npt_rx | number of parallel turns | turns |
| lrx_target | target rx length | m |
| mu_r | relative permeability | pu |
| density | material density | kg/L |
| rrx_conduit | radius of rx conduit | m |
| trx_conduit | thickness of rx conduit | m |
| mpl_rx | rx litz wire mass per length | kg/m |
| Rpl_rx | rx litz wire dc resistance per length | Ohms/m |
| ODrx_conduit | outer diameter of rx conduit | m |
| ODwire_rx | outer diameter of rx litz wire | m |
| yc_rx | y-position of rx conductor centers | m |
| yymin_rx | min y-position of rx core | m |

9. The method of claim 2, wherein the design geometry is based on a plurality of variables for the DWPT system.

10. The method of claim 9, wherein the plurality of variables for the DWPT system includes:

| Parameter | Description | Units |
|---|---|---|
| dₜᵣ | air gap between tx and rx | cm |
| t_sleeve | thickness of conductor jacket/sleeve | m |
| p_obs | stray field observation points | m |
| Pout | desired output power (transferred by the | W |
| | receiver) | |
| Vin_V | dcinput voltage (input to inverter coupled to | V |
| | transmitter) | |
| Tamb | ambient temperature | deg C. |
| TMax | max winding temperature | deg C. |
| freq | resonant frequency | Hz |
| Vout_V | desired output voltage out of rectifier of | V |
| | receiver | |
| rated_volt | maximum rated voltage for coil-to-coil in | V |
| | system | |
| Jmax | max conductor current density for all coils | A/m\hat{ }2 |
| BstrayMax | max stray field | T |
| current_ratio | ratio of tx to rx operating currents | unitless |
| dₜᵣ | air gap between tx and rx | cm |
| t_sleeve | thickness of conductor jacket/sleeve | m |
| k_bend | ratio of conductor bending radius to conductor | pu |
| | OD | |
| p_obs | stray field observation points | m |
| Pout | desired output power | W |
| Vin V | dcinput voltage | V |
| Tamb | ambient temperature | deg C. |
| TMax | max winding temperature | deg C. |
| freq | resonant frequency | Hz |
| Vout_V | desired output voltage | V |
| rated_volt | maximum rated voltage in system | V |
| Jmax | max conductor current density | A/m\hat{ }2 |
| BstrayMax | max stray field | T |
| mu0 | vacuum permeability | H/m |
| g | surface-to-surface air gap between tx and rx | m |
| current_ratio | ratio of tx to rx operating currents | pu |

11. An optimized coil design in a three-phase dynamic wireless power transfer (DWPT) system, comprising:
a first coil arrangement having three coils (C_{A}, C_{B}, and C_{C}), each coil constituting at least one cable disposed in a form and crossing each of the other two coils including two parallel straight segments and two parallel loop segments, the three coils thus representing self-inductances (L_{A}, L_{B}, and L_{C}) as well mutual inductance (L_{AB}, L_{BC}, and L_{AC}),
whereby the self-inductance and mutual inductance of the three coils are governed by inequalities:
$${Low}_{1} < \frac{{L}_{A} + 2 {L}_{BC}}{{L}_{B} + 2 {L}_{CA}} \leq {High}_{1}$$
$${Low}_{2} < \frac{{L}_{A} + 2 {L}_{BC}}{{L}_{C} + 2 {L}_{AB}} \leq {High}_{2}$$
$${Low}_{3} < \frac{{L}_{B} + 2 {L}_{CA}}{{L}_{C} + 2 {L}_{AB}} \leq {High}_{3}$$
wherein Low₁ is about 0.5 and High₁ is about 2,
Low₂ is about 0.5 and High₂ is about 2, and
Low₃ is about 0.5 and High₃ is about 2 for a an operational frequency band of between about 79 kHz and about 90 KHz.

12. The optimized coil design of claim 11, wherein the three coils of the first coil arrangement are proximate to a magnetic core.

13. The optimized coil design of claim 11, wherein the at least one cable in the first coil arrangement is two cables coupled to one another in a parallel manner.

14. The optimized coil design of claim 11, wherein the at least one cable in the first coil arrangement is two cables coupled to one another in a series manner.

15. The optimized coil design of claim 11, wherein the at least one cable in the first coil arrangement is three cables coupled to one another in a parallel manner.

16. The optimized coil design of claim 11, wherein the at least one cable in the first coil arrangement is three cables coupled to one another in a series manner.

17. The optimized coil design of claim 11, wherein the three coils in the first coil arrangement are configured to provide a wireless power transfer to a second coil arrangement, disposed a distance away from the first coil arrangement.

18. The optimized coil design of claim 17, wherein the second coil arrangement includes three coils (C_{X}, C_{Y}, and C_{Z}), each coil constituting at least one cable disposed in a form and crossing each of the other two coils including two parallel straight segments and two parallel loop segments, the three coils thus representing self-inductances (L_{X}, L_{Y}, and L_{Z}) as well mutual inductance (L_{XY}, L_{YZ}, and L_{XZ}),
whereby the self-inductance and mutual inductance of the three coils of the second coil arrangement are governed by inequalities:
$${Low}_{1} < \frac{{L}_{X} + 2 {L}_{YZ}}{{L}_{Y} + 2 {L}_{ZX}} \leq {High}_{1}$$
$${Low}_{2} < \frac{{L}_{X} + 2 {L}_{YZ}}{{L}_{Z} + 2 {L}_{XY}} \leq {High}_{2}$$
$${Low}_{3} < \frac{{L}_{Y} + 2 {L}_{ZX}}{{L}_{Z} + 2 {L}_{XY}} \leq {High}_{3} ,$$
and wherein the first coil arrangement and the second coil arrangement represent mutual inductances (M_{AX}, M_{BZ}, M_{CY}, M_{BY}, M_{CX}, M_{AZ}, M_{CZ}, M_{AY}, and M_{BX}) governed by inequalities:
$${Low}_{4} < \frac{{M}_{AX} + {M}_{BZ} + {M}_{CY}}{{M}_{BY} + {M}_{CX} + {M}_{AZ}} \leq {High}_{4}$$
$${Low}_{5} < \frac{{M}_{AX} + {M}_{BZ} + {M}_{CY}}{{M}_{CZ} + {M}_{AY} + {M}_{BX}} \leq {High}_{5}$$
$${Low}_{6} < \frac{{M}_{BY} + {M}_{CX} + {M}_{AZ}}{{M}_{CZ} + {M}_{AY} + {M}_{BX}} \leq {High}_{6} ,$$
wherein Low₄ is about 0.5 and High₄ is about 2,
Low₅ is about 0.5 and Highs is about 2, and
Low₆ is about 0.5 and High₆ is about 2 for a an operational frequency band of between about 79 kHz and about 90 kHz, wherein the first coil arrangement and the second coil arrangement are substantially aligned.

19. The optimized coil design of claim 18, wherein the three coils of the second coil arrangement are proximate to a magnetic core.

20. The optimized coil design of claim 18, wherein the at least one cable in the second coil arrangement is two cables coupled to one another in a parallel manner.

21. The optimized coil design of claim 18, wherein the at least one cable in the second coil arrangement is two cables coupled to one another in a series manner.

22. The optimized coil design of claim 18, wherein the at least one cable in the second coil arrangement is three cables coupled to one another in a parallel manner.

23. The optimized coil design of claim 18, wherein the at least one cable in the second coil arrangement is three cables coupled to one another in a series manner.

24. The optimized coil design of claim 19, wherein the three coils in the first coil arrangement and the coils in the second coil arrangement are separated by non-magnetic material.

25. The optimized coil design of claim 11, wherein
Low₁ is about 0.95 and High is about 1.05,
Low₂ is about 0.95 and High₂ is about 1.05, and
Low₃ is about 0.95 and High₃ is about 1.05.

26. The optimized coil design of claim 18, wherein
Low₄ is about 0.95 and High₄ is about 1.05,
Low₅ is about 0.95 and High₅ is about 1.05, and
Low₆ is about 0.95 and High₆ is about 1.05.
